(19) United States
(12) Patent Application Publication
(10) Pub. No.: US 2005/0196951 A1
(43) Pub. Date: Sep. 8, 2005

(54) METHOD OF FORMING DUAL DAMASCENE STRUCTURES

(76) Inventors: Benjamin Szu-Min Lin, Hsin-Chu City (TW); Shou-Wan Huang, Hsin-Chu City (TW)

Correspondence Address: NORTH AMERICA INTERNATIONAL PATENT OFFICE (NAIPC), P.O. BOX 506, MERRIFIELD, VA, 22116, US

(21) Appl. No.: 10/708,502

(22) Filed: Mar. 8, 2004

(51) Int. Cl. H01L 21/4763; H01L 21/311; H01L 21/76

(52) U.S. Cl. 438/622; 438/401

(57) ABSTRACT

A method of forming at least one wire on a substrate comprising at least one conductive region is provided. AnAn insulatingayer is disposed on the substrate. The method includes forming a hard mask layer on the insulating layer followed by forming at least one recess by removing portions of the hard mask layer and the insulating layer, forming a light blocking layer on the hard mask layer and the recess, and the light blocking layer and the hard mask layer forming a composite layer, forming a gap filling layer filling up the recess on the light blocking layer, forming a photoresist layer on the gap filling layer, aligning a photo mask with the recess by utilizing the composite layer as a mask, and performing an exposure/development process to form at least one pattern above the recess in the photoresist layer.

### BACKGROUND OF INVENTION

1. Field of the Invention

The present invention relates to a method of forming dual damascene structures, and more particularly, to a method utilizing two direct alignments to form dual damascene structures having a large via to trench bridging margin.

2. Description of the Prior Art

A dual damascene process is a method of forming a conductive wire coupled with a via plug in a dielectric layer. The dual damascene structure, comprising a trench and a via hole, is used to connect devices and wires in a semiconductor wafer within various layers and is isolated from other devices by the inter-layer dielectrics (ILD) around it. Since the resistivity of copper is smaller than the resistivity of aluminum (Al), a large current can be sustained in a small area. Consequently, chips having high speed, high integration, and high efficiency (with 30-40% improvement) are fabricated. To fill copper into the dual damascene structures thus becomes a trend in fabricating dual damascene copper wires. As integrated circuit technology advances, improving the yield of the dual damascene structure, simplifying the process flow and reducing the production cost are important issues in the manufacturing process of integrated circuits at the present time.

Please refer to FIG. 1 to FIG. 7. FIG. 1 to FIG. 7 are schematic diagrams of a method of fabricating dual damascene copper wires 58, 62 according to the prior art. As shown in FIG. 1, a semiconductor wafer 10 comprises a substrate 12, conductive layers 14,16,18 disposed on predefined regions of a surface of the substrate 12, and an inter layer dielectric (ILD) 22 disposed on the surface of the substrate 12 and covering the conductive layers 14,16,18. Since the other elements disposed on the surface of the substrate 12 are not the concerning parts in the dual damascene process, they are not shown in FIG. 1 and in other figures. Each of the conductive layers 14, 16 may be a source of a transistor, a gate of a transistor, a drain of a transistor, a lower level wire, a landing pad, or a resistor, and the conductive layer 18 is an alignment mark.

A hard mask layer 24 is formed on a surface of the inter layer dielectric 22 first. The hard mask layer 24 is a titanium nitride layer (TiN layer), and a thickness of the hard mask layer 24 is approximately 250 angstroms (Å). As shown in FIG. 2, a photo-etching-process (PEP) is then performed to form via patterns 26, 28 in the hard mask layer 24 and the inter layer dielectric 22 by removing portions of the hard mask layer 24 and the inter layer dielectric 22 until reaching a top surface of the conductive layers 14, 16. A via pattern 32 is simultaneously formed aside the conductive layer 18 in the hard mask layer 24 and the inter layer dielectric 22 by removing portions of the hard mask layer 24 and the inter layer dielectric 22.

In the photo-etching-process, light source (not shown) with a wavelength of 633 nm is utilized to generate alignment light beams. Under the circumstances, the hard mask layer 24 is transparent to the alignment light beams to achieve direct alignment by aligning a photo mask (not shown) with the conductive layer 18 that is used as the alignment mark. Consequently, the via patterns 26, 28 expose portions of the conductive layers 14, 16, respectively.

As shown in FIG. 3, a bottom anti-reflective coating (BARC) 34 is formed on the semiconductor wafer 10 by a spin coating process. Since the spin coating process is featured by good step coverage ability, the via patterns 26, 28, 32 are filled with the bottom anti-reflective coating 34. Therefore, the bottom anti-reflective coating 34 is also called a gap filling layer. After that, a photoresist layer 36 is formed on a surface of the bottom anti-reflective coating 34.

As shown in FIG. 4, an alignment process is thereafter performed to align another photo mask (not shown) with the conductive layer 18 that is used as the alignment mark. Then, an exposure process and a development process are performed to form trench patterns 38 in the photoresist layer 36 followed by an etching process. The etching process removes portions of the bottom anti-reflective coating 34, the hard mask layer 24, and the inter layer dielectric 22 to form trenches 42, 44 on top of vias 46, 48, respectively.

When performing the alignment process, light source (not shown) with the wavelength of 633 nm is utilized again to generate alignment light beams. Since the bottom anti-reflective coating 34, the hard mask layer 24, and the inter layer dielectric 22 are all transparent to the alignment light beams, indirect alignment is thus achieved by aligning the photo mask (not shown) with the alignment mark (the conductive layer 18).

As shown in FIG. 5, the photoresist layer 36 is removed. After that, the remaining bottom anti-reflective coating 34 is removed. A barrier layer 52 is then formed on a surface of the trenches 42, 44, the vias 46, 48 and the hard mask layer 24. As shown in FIG. 6, a re-sputter process is thereafter performed to re-shape the barrier layer 52 such that the conductive regions 14, 16 are exposed. Then, a seed layer 54 is formed on a surface of the barrier layer 52 and on a surface of the exposed conductive regions 14, 16. Later, a metal layer 56, such as a copper (Cu) layer, is formed on a surface of the seed layer 54, and the metal layer 56 fills up the trenches 42, 44, and the vias 46, 48.

Finally, a chemical mechanical polishing (CMP) process is performed by utilizing the barrier layer 52 as an end-point to remove the metal layer 56 and the seed layer 54 disposed outside the trenches 42, 44 and the vias 46, 48, as shown in FIG. 7. As a result, the remaining metal layer 56 inside the trenches 42, 44 and the vias 46, 48 is aligned with the surface of the barrier layer 52 disposed outside the trenches 42, 44 to complete the fabrication of the dual damascene copper wires 58, 62.

The prior art method is not only applied to a via first dual damascene process shown in FIG. 1 to FIG. 7, but is also applied to a trench first dual damascene process. In the trench first dual damascene process, the photo-etching-process does not expose the top surface of the conductive layers 14, 16, and trenches are formed first followed by the formation of vias.

In the prior art method, no matter a via pattern is formed first or a trench pattern is formed first, the first alignment is a direct alignment, and the second alignment is an indirect alignment. Please refer to FIG. 8, FIG. 8 is a schematic diagram illustrating via to trench bridging due to alignment errors according to the prior art method. In FIG. 8, the dotted lines illustrate the ideal situation, while the solid lines illustrate the real situation. As shown in FIG. 8, when the alignment error of the first alignment is σ₁, via patterns 72, 74 are shifted toward right at a distance of σ₁ from the ideal situation. However, when the alignment error of the second alignment is −σ₂, trenches 76, 78 are shifted toward left at a distance of σ₂ from the ideal situation. Therefore, the via to trench bridging phenomenon tends to occur due to the accumulative alignment error.

Theoretically with such a methodology, the accumulative alignment error is √2 times the alignment error of a single alignment. In order to avoid the via to trench bridging phenomenon, the via to trench bridging margin is always very narrow under the circumstances to cause problems in processing and decreased production yield rate. Therefore, it is very important to develop a new lithography method to form dual damascene Cu wires having a large via to trench bridging margin and increased yield rate without causing problems in processes.

### SUMMARY OF INVENTION

It is therefore an objective of the claimed invention to provide a method utilizing two direct alignments to form dual damascene structures to resolve the abovementioned problems.

According to the claimed invention, at least one wire is formed on a substrate. The substrate comprises at least one conductive region, and an insulating layer is disposed on the substrate. The method includes forming a hard mask layer on a surface of the insulating layer, forming at least one recess by removing portions of the hard mask layer and portions of the insulating layer, forming a light blocking layer on a surface of the hard mask layer and the recess, and the light blocking layer and the hard mask layer forming a composite layer, forming a gap filling layer on a surface of the light blocking layer, and the gap filling layer filling up the recess, forming a photoresist layer on a surface of the gap filling layer, aligning a photo mask with the recess by utilizing the composite layer as a mask, and performing an exposure and development process to form at least one pattern above the recess in the photoresist layer.

It is an advantage of the present invention that the present invention method of forming the dual damascene copper wire is to form the composite layer or the bottom anti-reflective coating opaque to the alignment light beams. Therefore, the alignment light beams are prevented from reaching to the alignment mark in the second alignment process to achieve two direct alignments to improve alignment accuracy. The via to trench bridging phenomenon is thus avoided. The via to trench bridging margin is enlarged to avoid problems usually occurring in the prior art fabricating method which utilizes one direct alignment and one indirect alignment. As a result, the production yield rate is improved. In addition, the alignment signal is not influenced by the inter layer dielectric to reduce the alignment signal noise even when there is thickness variation in the inter layer dielectric. The signal strength is maximized and the alignment accuracy is improved.

These and other objectives of the claimed invention will no doubt become obvious to those of ordinary skill in the art after reading the following detailed description of the preferred embodiment, which is illustrated in the multiple figures and drawings.

### BRIEF DESCRIPTION OF DRAWINGS

FIG. 1 to FIG. 7 are schematic diagrams of a method of fabricating dual damascene copper wires according to the prior art.

FIG. 8 is a schematic diagrams illustrating via to trench bridging due to alignment errors according to the prior art method.

FIG. 9 to FIG. 15 are schematic diagrams of a method of fabricating dual damascene copper wires according to a first preferred embodiment of the present invention.

FIG. 16 to FIG. 22 are schematic diagrams of a method of fabricating dual damascene copper wires according to a second preferred embodiment of the present invention.

FIG. 23 to FIG. 25 are schematic diagrams of a method of fabricating dual damascene copper wires according to a third preferred embodiment of the present invention.

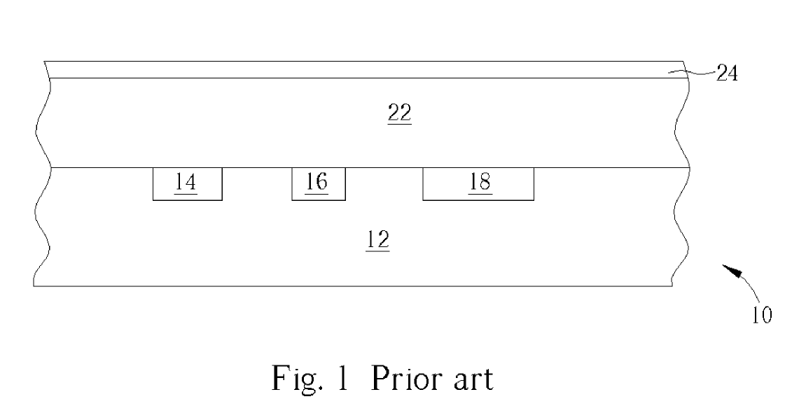

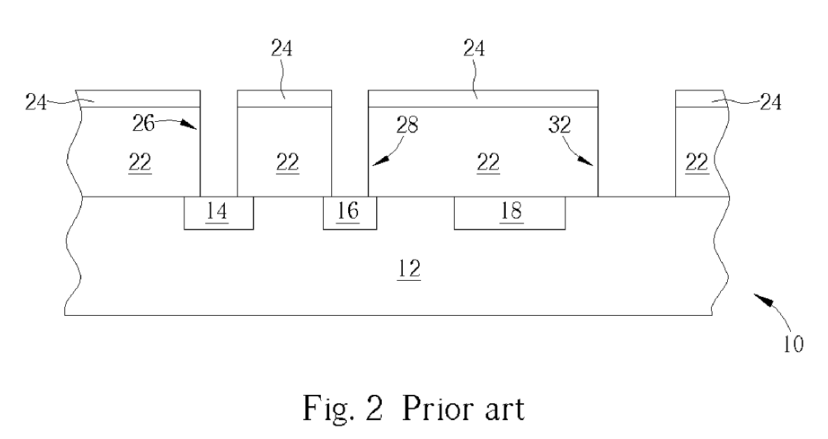

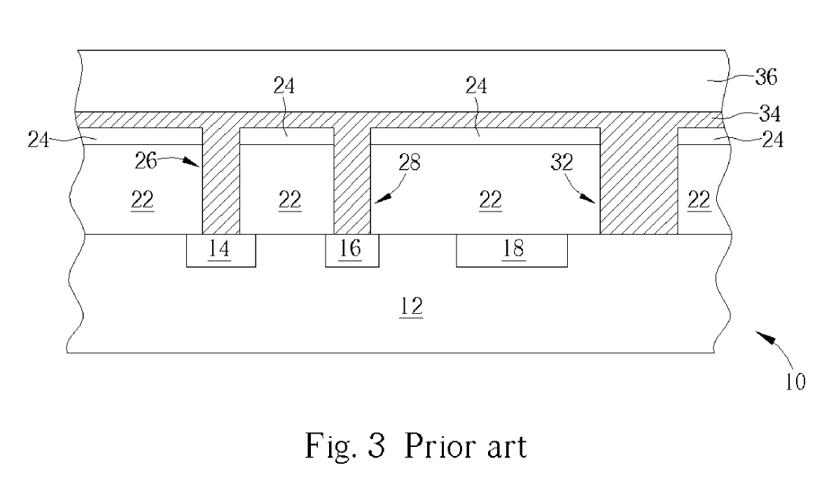

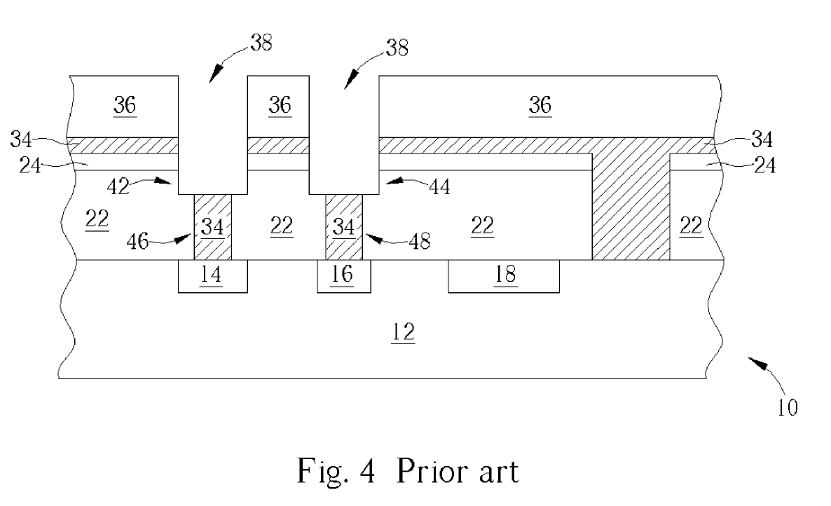

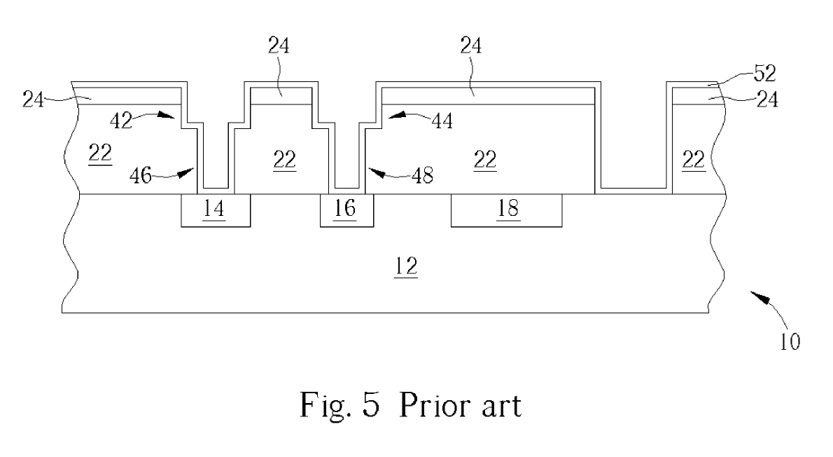

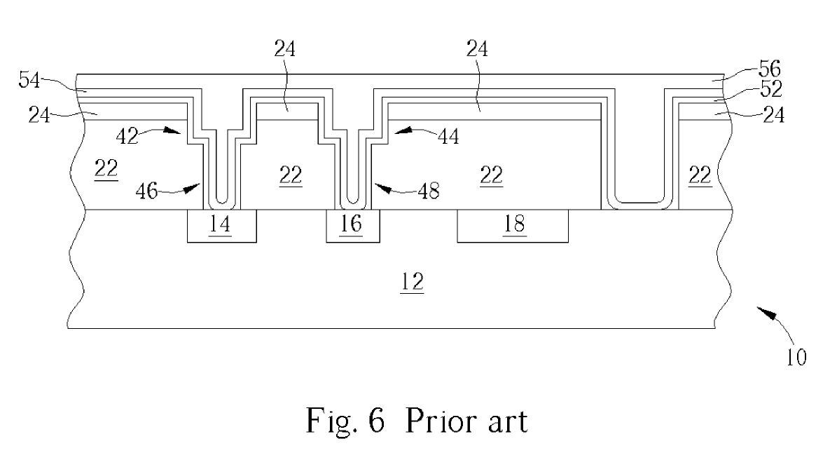

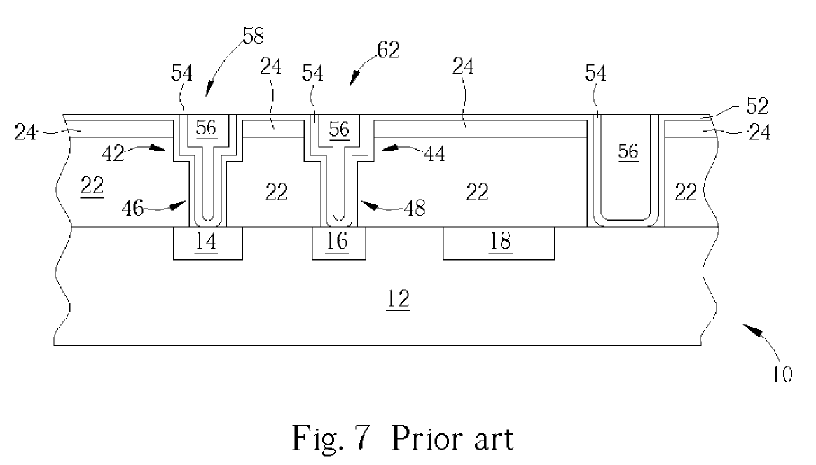

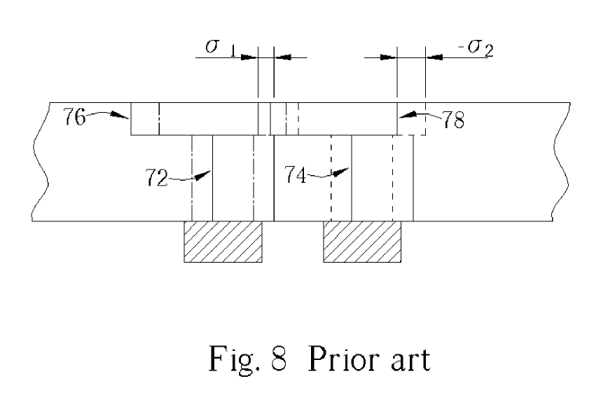

### DETAILED DESCRIPTION

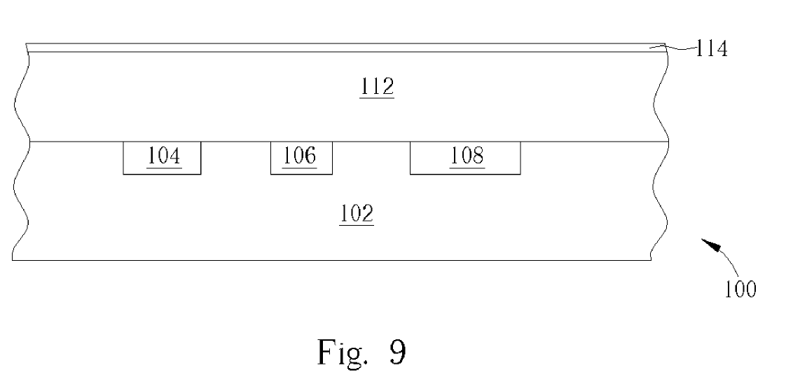

Please refer to FIG. 9 to FIG. 15. FIG. 9 to FIG. 15 are schematic diagrams of a method of fabricating dual damascene copper wires 154, 156 according to a first preferred embodiment of the present invention. As shown in FIG. 9, a semiconductor wafer 100 comprises a substrate 102, conductive layers 104, 106, 108 disposed on predefined regions of a surface of the substrate 102, and an inter layer dielectric 112 disposed on the surface of the substrate 102 and covering the conductive layers 104, 106, 108. Since the other elements disposed on the surface of the substrate 102 are not the concerning parts in the dual damascene process, they are not shown in FIG. 9 and in other figures. Each of the conductive layers 104, 106 may be a source of a transistor, a gate of a transistor, a drain of a transistor, a lower level wire, a landing pad, or a resistor, and the conductive layer 108 is an alignment mark.

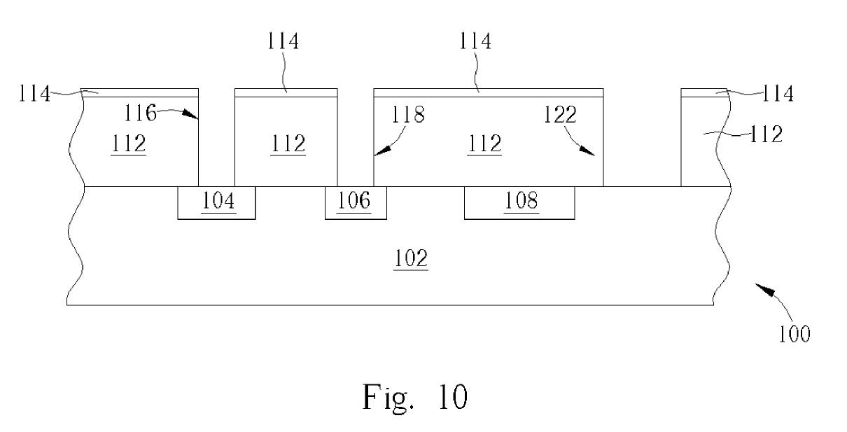

A hard mask layer 114 is formed on a surface of the inter layer dielectric 112 first. The hard mask layer 114 is a titanium nitride layer, and a thickness of the hard mask layer 114 is approximately 250 angstroms (Å). As shown in FIG. 10, a photo-etching-process (PEP) is then performed to form via patterns 116, 118 in the hard mask layer 114 and the inter layer dielectric 112 by removing portions of the hard mask layer 114 and the inter layer dielectric 112 until reaching a top surface of the conductive layers 104, 106. A via pattern 122 is simultaneously formed aside the conductive layer 108 in the hard mask layer 114 and the inter layer dielectric 112 by removing portions of the hard mask layer 114 and the inter layer dielectric 112.

In the photo-etching-process, light source (not shown) with a wavelength of 633 nm is utilized to generate alignment light beams. Under the circumstances, the hard mask layer 114 is transparent to the alignment light beams to achieve direct alignment by aligning a photo mask (not shown) with the conductive layer 108 that is used as the alignment mark. Consequently, the via patterns 116, 118 expose portions of the conductive layers 104, 106 respectively.

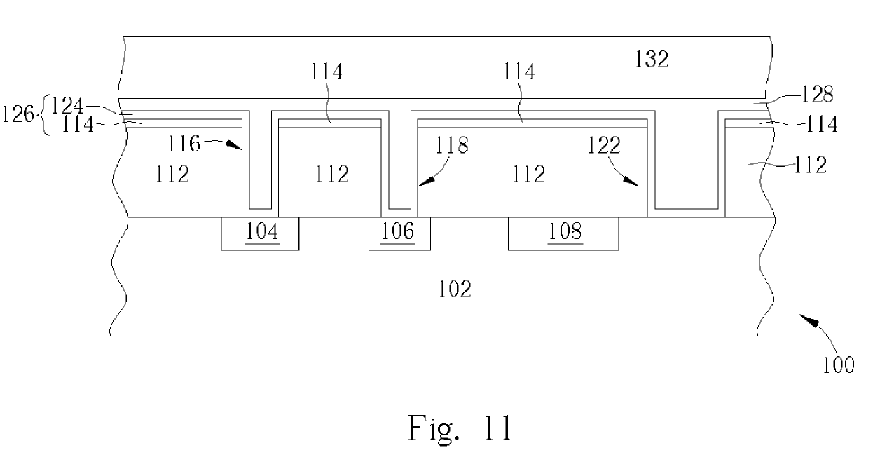

As shown in FIG. 11, a metal liner layer 124 is formed on a surface of the hard mask layer 114, the via patterns 116, 118, and the via pattern 122. The metal liner layer 124 comprises a titanium nitride layer or a tantalum nitride layer (TaN layer). In FIG. 11, the metal liner layer 124 is another titanium nitride layer, and a thickness of the metal liner layer 124 is approximately 250 angstroms (Å). The metal liner layer 124 and the hard mask layer 114 thus form a composite layer 126. A bottom anti-reflective coating 128 is then formed on the semiconductor wafer 100 by a spin coating process. Since the spin coating process is featured by good step coverage ability, the via patterns 116, 118, 122 are filled with the bottom anti-reflective coating 128. Therefore, the bottom anti-reflective coating 128 is also called a gap filling layer. After that, a photoresist layer 132 is formed on a surface of the bottom anti-reflective coating 128.

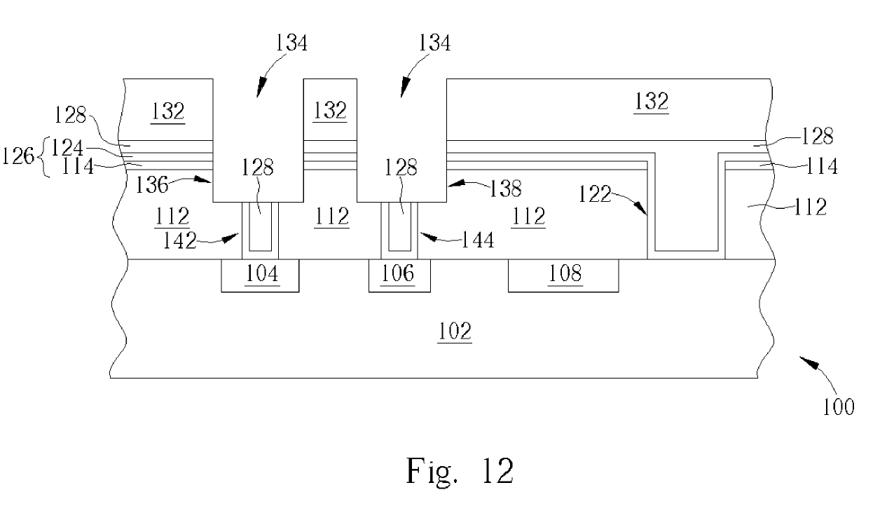

As shown in FIG. 12, an alignment process is thereafter performed to align another photo mask (not shown) with the via pattern 122, rather than the alignment mark (the conductive layer 108). Then, an exposure process and a development process are performed to form trench patterns 134 in the photoresist layer 132 followed by an etching process. The etching process removes portions of the bottom anti-reflective coating 128, the metal liner layer 124, the hard mask layer 114, and the inter layer dielectric 112 to form trenches 136, 138 on top of vias 142, 144, respectively.

When performing the alignment process, light source (not shown) with the wavelength of 633 nm is utilized again to generate alignment light beams. Since the composite layer 126, composed of titanium nitride and having a thickness of 500 angstroms (Å) is opaque to alignment light beams, the photo mask (not shown) is not aligned with the alignment mark (the conductive layer 108) any more. Rather, direct alignment is achieved by aligning the photo mask (not shown) with the via pattern 122 because the bottom anti-reflective coating 128 is transparent to the alignment light beams.

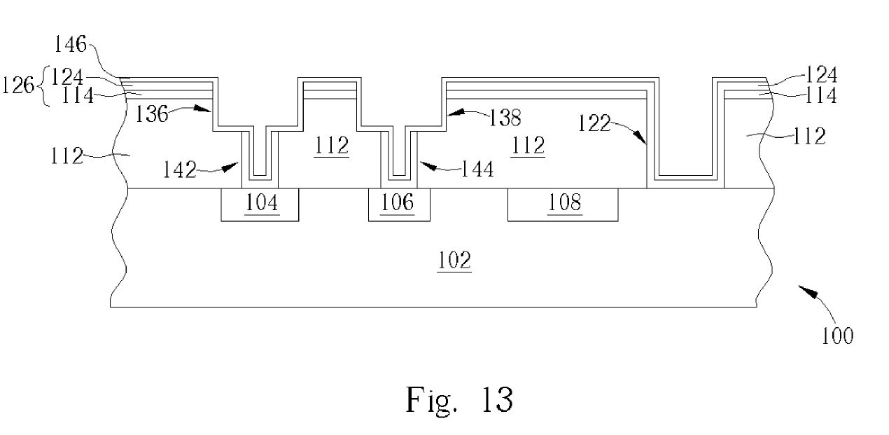

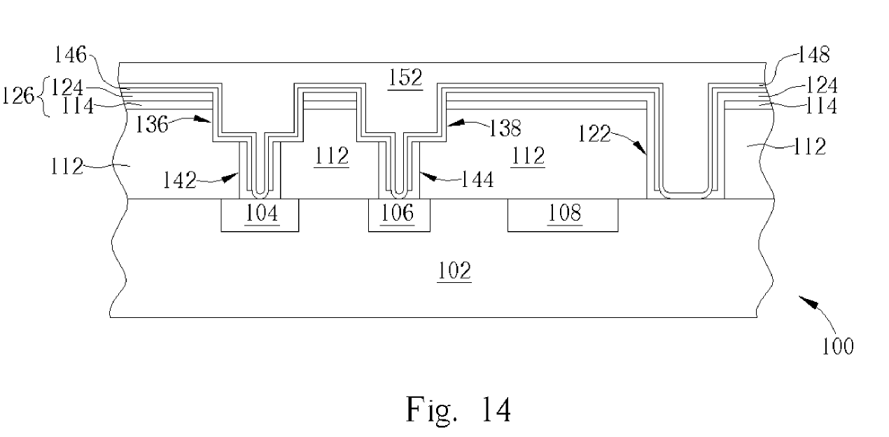

As shown in FIG. 13, the photoresist layer 132 is removed. After that, the remaining bottom anti-reflective coating 128 is removed. A barrier layer 146 is then formed on a surface of the trenches 136, 138, the vias 142, 144 and the metal liner layer 124. As shown in FIG. 14, a re-sputter process is thereafter performed to re-shape the barrier layer 146 and the remaining metal liner layer 124 such that the conductive regions 104, 106 are exposed. Then, a seed layer 148 is formed on a surface of the barrier layer 146 and on a surface of the exposed conductive regions 104, 106. Later, a metal layer 152, such as a copper layer, is formed on a surface of the seed layer 148, and the metal layer 152 fills up the trenches 136, 138, and the vias 142, 144.

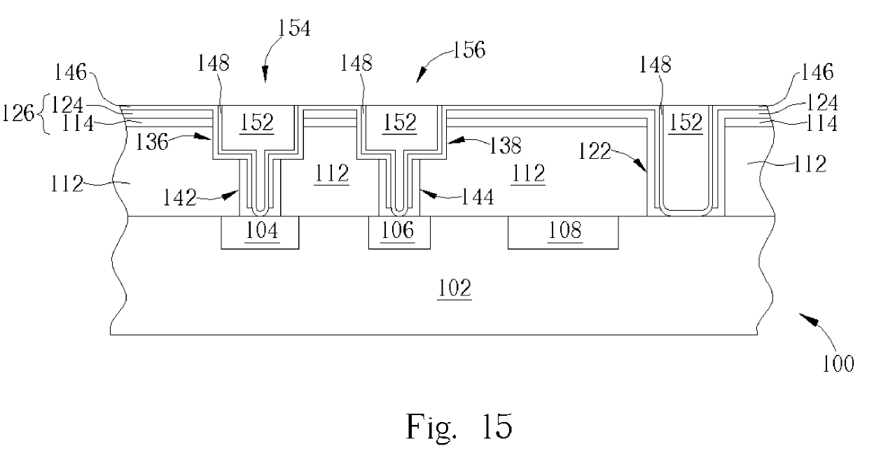

Finally, a chemical mechanical polishing process is performed by utilizing the barrier layer 146 as an end-point to remove the metal layer 152 and the seed layer 148 disposed outside the trenches 136, 138 and the vias 142, 144, as shown in FIG. 15. As a result, the remaining metal layer 152 inside the trenches 136, 138 and the vias 142, 144 is aligned with the surface of the barrier layer 146 disposed outside the trenches 136, 138 to complete the fabrication of the dual damascene copper wires 154, 156.

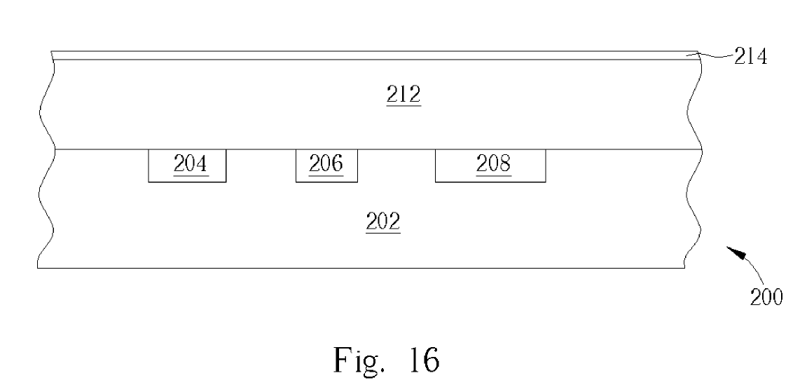

The present invention method is not only applied to a via first dual damascene process shown in FIG. 9 to FIG. 15, but is also applied to a trench first dual damascene process. Please refer to FIG. 16 to FIG. 22. FIG. 16 to FIG. 22 are schematic diagrams of a method of fabricating dual damascene copper wires 254, 256 according to a second preferred embodiment of the present invention. As shown in FIG. 16, a semiconductor wafer 200 comprises a substrate 202, conductive layers 204, 206, 208 disposed on predefined regions of a surface of the substrate 202, and an inter layer dielectric 212 disposed on the surface of the substrate 202 and covering the conductive layers 204, 206, 208. Each of the conductive layers 204, 206 may be a source of a transistor, a gate of a transistor, a drain of a transistor, a lower level wire, a landing pad, or a resistor, and the conductive layer 208 is an alignment mark.

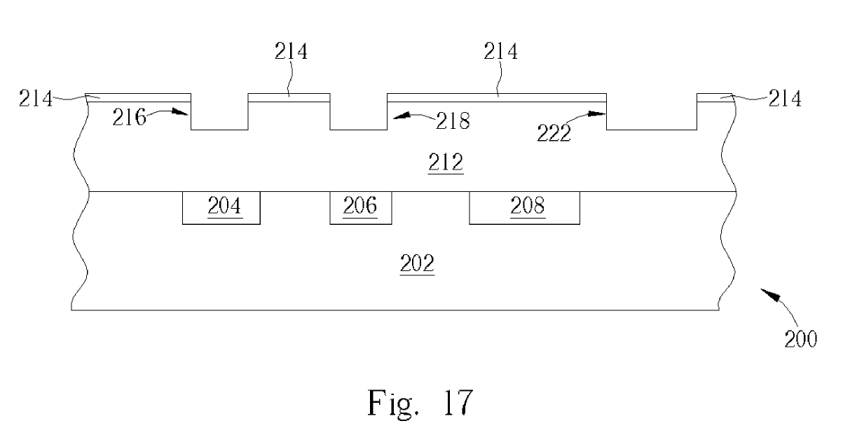

A hard mask layer 214 is formed on a surface of the inter layer dielectric 212 first. The hard mask layer 214 is a titanium nitride layer, and a thickness of the hard mask layer 214 is approximately 250 angstroms (Å). As shown in FIG. 17, a photo-etching-process (PEP) is then performed to form trench patterns 216, 218 in the hard mask layer 214 and the inter layer dielectric 212 by removing portions of the hard mask layer 214 and the inter layer dielectric 212. A trench pattern 222 is simultaneously formed aside the conductive layer 208 in the hard mask layer 214 and the inter layer dielectric 212 by removing portions of the hard mask layer 214 and the inter layer dielectric 212. In the photo-etching-process, light source (not shown) with a wavelength of 633 nm is utilized to generate alignment light beams. Under the circumstances, the hard mask layer 214 is transparent to the alignment light beams to achieve direct alignment by aligning a photo mask (not shown) with the conductive layer 208 that is used as the alignment mark.

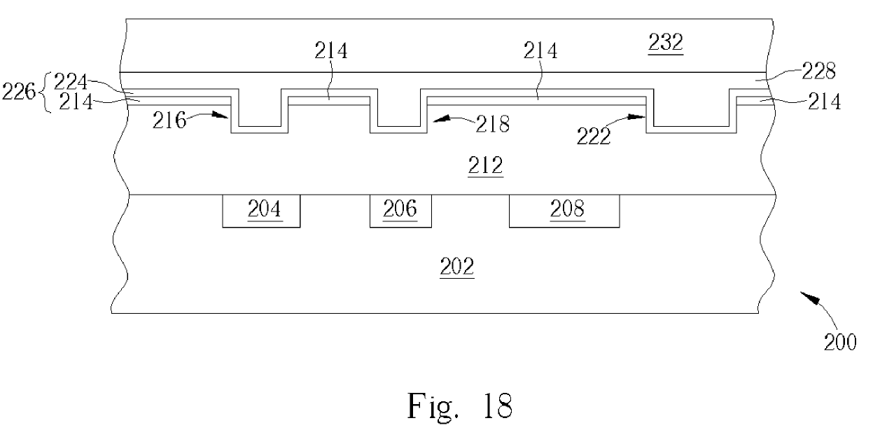

As shown in FIG. 18, a metal liner layer 224 is formed on a surface of the hard mask layer 214, the trench patterns 216, 218, and the trench pattern 222. The metal liner layer 224 comprises a titanium nitride layer or a tantalum nitride layer. In FIG. 18, the metal liner layer 224 is another titanium nitride layer, and a thickness of the metal liner layer 224 is approximately 250 angstroms (Å). The metal liner layer 224 and the hard mask layer 214 thus form a composite layer 226. A bottom anti-reflective coating 228 is then formed on the semiconductor wafer 200 by a spin coating process. Since the spin coating process is featured by good step coverage ability, the trench patterns 216, 218, 222 are filled with the bottom anti-reflective coating 228. Therefore, the bottom anti-reflective coating 228 is also called a gap filling layer. After that, a photoresist layer 232 is formed on a surface of the bottom anti-reflective coating 228.

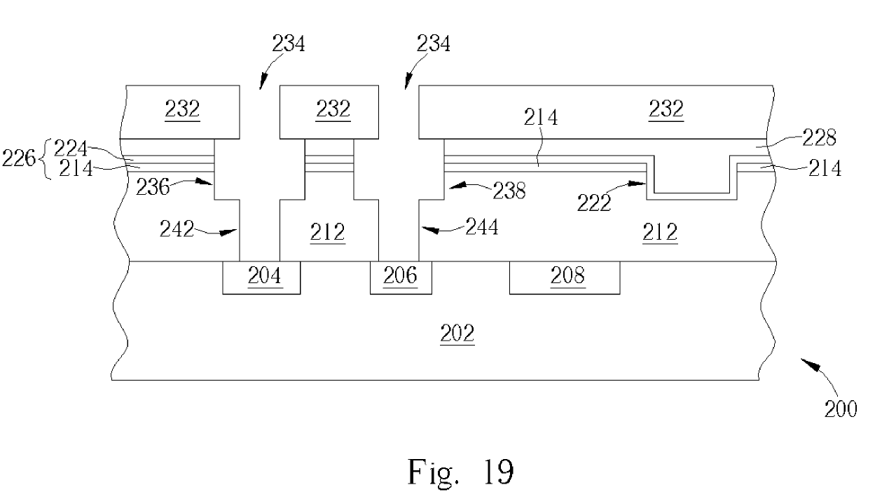

As shown in FIG. 19, an alignment process is thereafter performed to align another photo mask (not shown) with the trench pattern 222, rather than the alignment mark (the conductive layer 208). Then, an exposure process and a development process are performed to form via patterns 234 in the photoresist layer 232 followed by an etching process. The etching process removes portions of the bottom anti-reflective coating 228, the metal liner layer 224, the hard mask layer 214, and the inter layer dielectric 212 to form trenches 236, 238 on top of vias 242, 244, respectively.

When performing the alignment process, light source (not shown) with the wavelength of 633 nm is utilized again to generate alignment light beams. Since the composite layer 226, composed of titanium nitride and having a thickness of 500 angstroms (Å) is opaque to alignment light beams, the photo mask (not shown) is not aligned with the alignment mark (the conductive layer 208) any more. Rather, direct alignment is achieved by aligning the photo mask (not shown) with the trench pattern 222 because the bottom anti-reflective coating 228 is transparent to the alignment light beams.

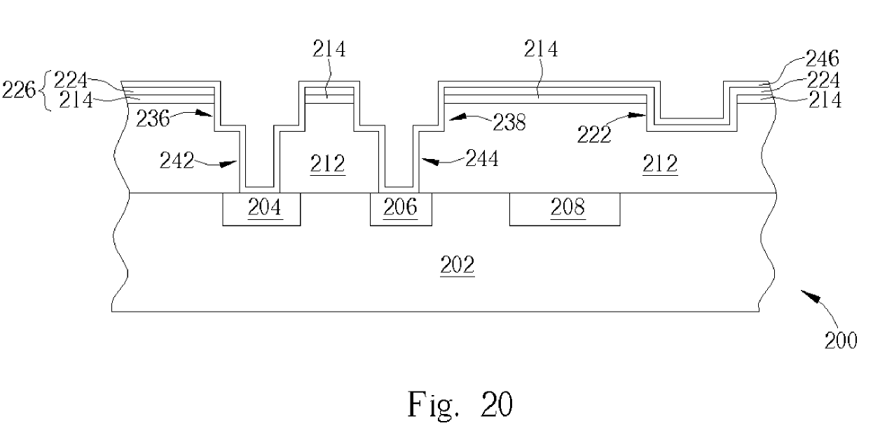

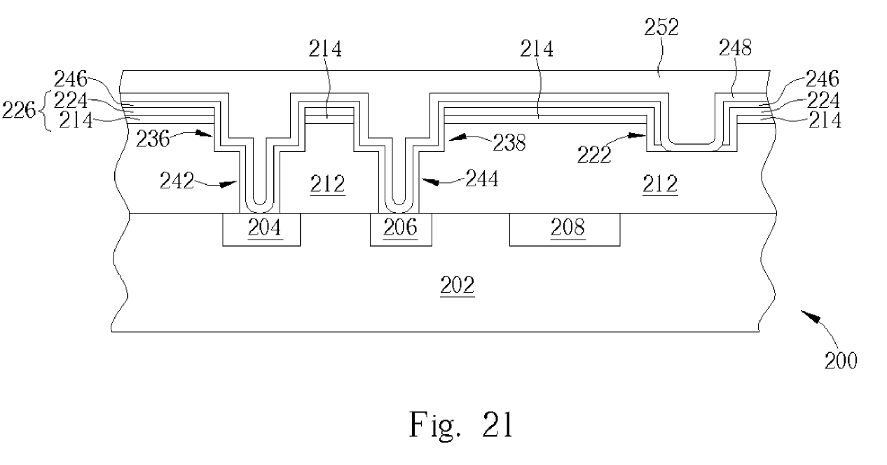

As shown in FIG. 20, the photoresist layer 232 is removed. After that, the remaining bottom anti-reflective coating 228 is removed. A barrier layer 246 is then formed on a surface of the trenches 236, 238, the vias 242, 244 and the metal liner layer 224. As shown in FIG. 21, a re-sputter process is thereafter performed to re-shape the barrier layer 246 such that the conductive regions 204, 206 are exposed. Then, a seed layer 248 is formed on a surface of the barrier layer 246 and on a surface of the exposed conductive regions 204, 206. Later, a metal layer 252, such as a copper layer, is formed on a surface of the seed layer 248, and the metal layer 252 fills up the trenches 236, 238, and the vias 242, 244.

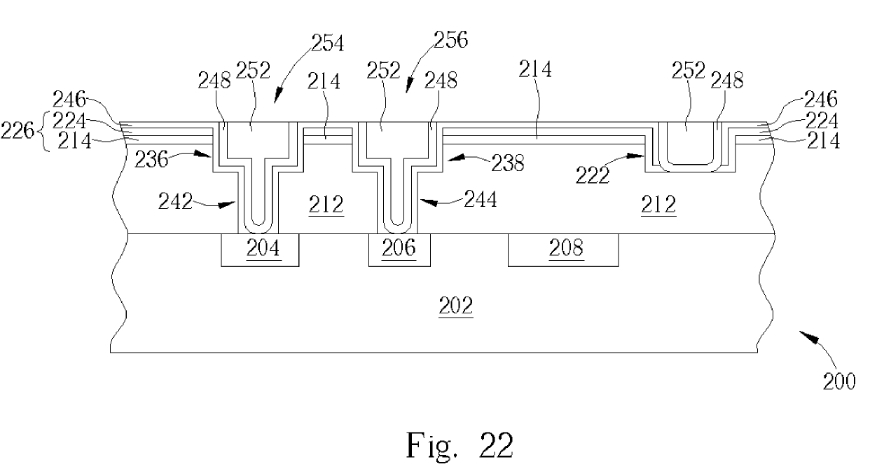

Finally, a chemical mechanical polishing process is performed by utilizing the barrier layer 246 as an end-point to remove the metal layer 252 and the seed layer 248 disposed outside the trenches 236, 238 and the vias 242, 244, as shown in FIG. 22. As a result, the remaining metal layer 252 inside the trenches 236, 238 and the vias 242, 244 is aligned with the surface of the barrier layer 246 disposed outside the trenches 236, 238 to complete the fabrication of the dual damascene copper wires 254, 256.

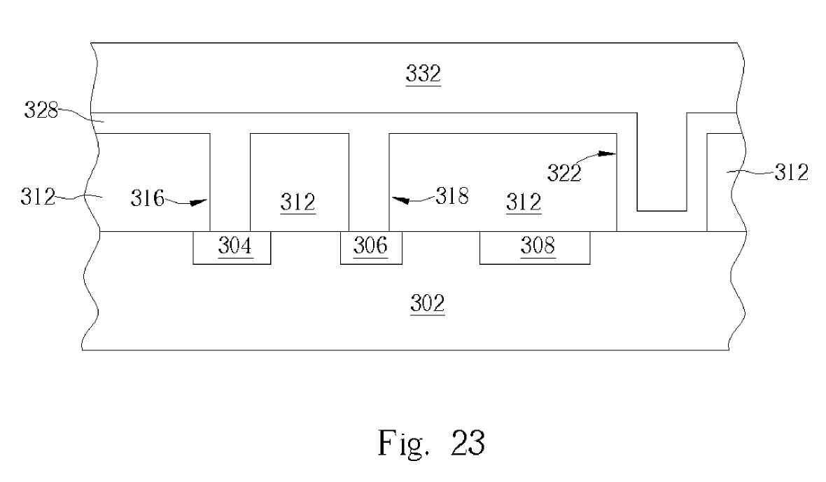

In the above two preferred embodiments, metal linear layers 124, 224 are utilized to improve light absorption ability to allow two direct alignments to be performed. However, light absorption ability can be improved by modifying the bottom anti-reflective coating. Please refer to FIG. 23 to FIG. 25. FIG. 23 to FIG. 25 are schematic diagrams of a method of fabricating dual damascene copper wires 354, 356 according to a third preferred embodiment of the present invention. As shown in FIG. 23, via patterns 316, 318 are formed in the inter layer dielectric 312 by a photo-etching-process to remove portions of the inter layer dielectric 312 until reaching a top surface of conductive layers 304, 306. A via pattern 322 is simultaneously formed aside a conductive layer 308 in the inter layer dielectric 312 by removing portions of the inter layer dielectric 312.

In the photo-etching-process, the inter layer dielectric 312 is transparent to alignment light beams to achieve direct alignment by aligning a photo mask (not shown) with the conductive layer 308 that is used as the alignment mark. Later, an organic bottom anti-reflective coating 328 is formed on a surface of the inter layer dielectric 312 and the via patterns 316, 318, 322. In this preferred embodiment, the bottom anti-reflective coating 328 is able to absorb reflected exposure light beams (usually having a wavelength of 193 nm or 248 nm) and alignment light beams having a wavelength of 633 nm. In addition, the organic bottom anti-reflective coating 328 is formed by the spin coating process.

After this, exposure light beams falling on a substrate 302 through a photoresist layer 332 undergo an infinite series of reflections at the boundary between the photoresist layer 332 and the air as well as at the boundary between the photoresist layer 332 and the inter layer dielectric 312 if there is no bottom anti-reflective coating 328. Therefore, the incoming and outgoing waves interfere in the photoresist layer 332 to produce swing curve. In order to resolve this problem, the bottom anti-reflective coating 328 is utilized to control swing curve and unwanted reflectivity. The composition and thickness of the bottom anti-reflective coating 328 are determined through complicated calculation to make the bottom anti-reflective coating 328 absorb reflected exposure light beams having a specific wavelength. In order to make the bottom anti-reflective coating 328 absorb the alignment light beams, dyes are added into the bottom anti-reflective coating 328. Since each kind of dye molecules has its specific unsaturated links and each of the unsaturated links has its specific absorption wavelength, the dyed bottom anti-reflective coating 328 can absorb the visible alignment light beams by adding proper dye molecules. A thickness of the organic bottom anti-reflective coating 328 is approximately 600˜1200 Å.

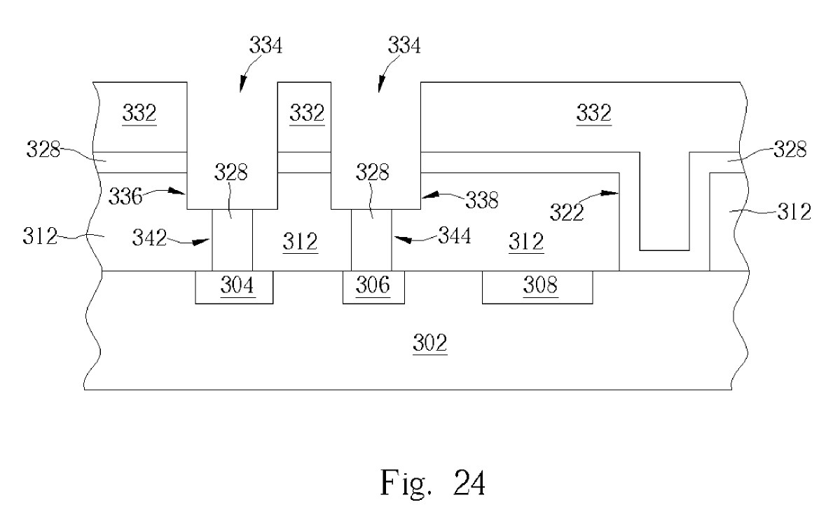

With such a thickness, the via patterns 216, 218, are filled with the bottom anti-reflective coating 328, but the via pattern 322 is not filled with the bottom anti-reflective coating 328 even though the spin coating process is featured by good step coverage ability. When the photoresist layer 332 is formed on a surface of the bottom anti-reflective coating 328, the via pattern 322 is filled with the photoresist layer 332. After that, an alignment process is performed to align another photo mask (not shown) with the via pattern 322, rather than the alignment mark (the conductive layer 308), as shown in FIG. 24. An exposure process and a development process are then performed to form trench patterns 334 in the photoresist layer 332 followed by an etching process. The etching process removes portions of the bottom anti-reflective coating 328 and the inter layer dielectric 312 to form trenches 336, 338 on top of vias 342, 344, respectively.

When performing the alignment process, light source (not shown) with the wavelength of 633 nm is utilized again to generate alignment light beams. Since the photoresist layer 332 is transparent to alignment light beams and the bottom anti-reflective coating 328 is opaque to alignment light beams, the photo mask (not shown) is not aligned with the alignment mark (the conductive layer 308) any more. Rather, direct alignment is achieved by aligning the photo mask (not shown) with the via pattern 322.

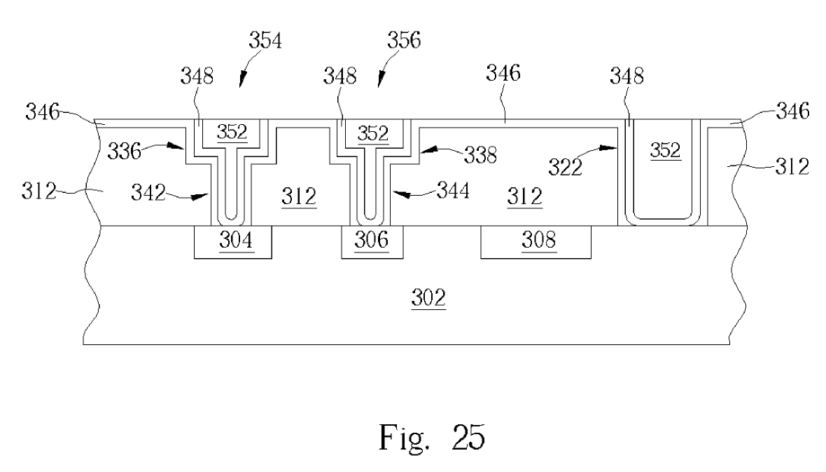

As shown in FIG. 25, the photoresist layer 332 is removed. After that, the remaining bottom anti-reflective coating 328 is removed. A barrier layer 346 is then formed on a surface of the trenches 336, 338, the vias 342, 344, and the inter layer dielectric 312 followed by a re-sputter process to re-shape the barrier layer 346 such that the conductive regions 304, 306 is exposed. A seed layer 348 is thereafter formed on a surface of the barrier layer 346 and on a surface of the exposed conductive regions 304, 306. Finally, a metal layer 352, such as a copper layer, is formed on a surface of the seed layer 348 followed by a chemical mechanical polishing process to remove the metal layer 352 and the seed layer 348 disposed outside the trenches 336, 338 and the vias 342, 344 to complete the fabrication of the dual damascene copper wires 354, 356.

The method mentioned in the third preferred embodiment of the present invention is not only applied to a via first dual damascene process shown in FIG. 23 to FIG. 25, but is also applied to a trench first dual damascene process. In addition, the present invention method may be applied to a silicon-on-insulator substrate (SOI substrate). Furthermore, the wavelength of the alignment light beams is not limited in 633 nm, the alignment light beams with a wavelength of 532 nm may be utilized. Under the circumstances, the same results can be achieved by adjusting the compositions and/or thickness of the hard mask layer and/or the metal liner layer, or the bottom anti-reflective coating.

According to the present invention method of forming the dual damascene cooper wire, the composite layer or the bottom anti-reflective coating opaque to the alignment light beams is formed to prevent the alignment light beams from reaching to the alignment mark in the second alignment process to achieve two direct alignments. No only is the via to trench bridging phenomenon avoided, but also the via to trench bridging margin is enlarged to avoid problems in processing. When applying the present invention method to a practical production line, the production yield rate is obviously improved.

In contrast to the prior art method, the present invention method of forming the dual damascene copper wire is to form the composite layer or the bottom anti-reflective coating opaque to the alignment light beams. Therefore, the alignment light beams are prevented from reaching to the alignment mark in the second alignment process to achieve two direct alignments to improve alignment accuracy. The via to trench bridging phenomenon is thus avoided. The via to trench bridging margin is enlarged to avoid problems usually occurring in the prior art fabricating method which utilizes one direct alignment and one indirect alignment. As a result, the production yield rate is improved. In addition, the alignment signal is not influenced by the inter layer dielectric to reduce the alignment signal noise even when there is thickness variation in the inter layer dielectric. The signal strength is maximized and the alignment accuracy is improved.

Those skilled in the art will readily observe that numerous modifications and alterations of the device may be made while retaining the teachings of the invention. Accordingly, the above disclosure should be construed as limited only by the metes and bounds of the appended claims.

1. A method of forming at least one wire on a substrate, the substrate comprising at least one conductive region, wherein the conductive region is utilized as a first alignment mark, an insulating layer disposed on the substrate, the method comprising:
forming a hard mask layer on a surface of the insulating layer;
forming at least one recess by removing portions of the hard mask layer and portions of the insulating layer;
forming a light blocking layer on a surface of the hard mask layer and the recess, the light blocking layer and the hard mask layer forming a composite layer;
forming a gap filling layer on a surface of the light blocking layer, and the gap filling layer filling up the recess;
forming a photoresist layer on a surface of the gap filling layer;
aligning a photo mask with the recess by utilizing the composite layer as a mask, wherein the recess is utilized as a second alignment mark, and light is prevented from reaching to the first alignment mark when aligning the photo mask with the second alignment mark to achieve two direct alignments; and
performing an exposure and development process to form at least one pattern above the recess in the photoresist layer.

2. The method of claim 1 wherein the substrate comprises a semiconductor wafer or a silicon-on-insulator substrate (SOI substrate).

3. The method of claim 1 wherein the conductive region comprises a source of a transistor, a gate of a transistor, a drain of a transistor, a lower level wire, a landing pad, or a resistor, and the recess is formed above the conductive region.

4. The method of claim 3 wherein the recess exposes the conductive region.

5. The method of claim 4 further comprising the following steps after forming the pattern in the photoresist layer:
performing an etching process by utilizing the photoresist layer as a mask to remove portions of the gap filling layer, the light blocking layer, the hard mask layer, and the insulating layer to form at least one trench of at least one dual damascene structure;
removing the photoresist layer;
removing the remaining gap filling layer;
forming a barrier layer on a surface of the light blocking layer and the dual damascene structure;
performing a re-sputter process to expose the conductive region;
forming a seed layer on a surface of the barrier layer and the exposed conductive layer; and
forming a metal layer on a surface of the seed layer, and the metal layer filling up the dual damascene structure.

6. The method of claim 3 wherein the recess does not expose the conductive region.

7. The method of claim 6 further comprising the following steps after forming the pattern in the photoresist layer:
performing an etching process by utilizing the photoresist layer as a mask to remove portions of the gap filling layer, the light blocking layer, the hard mask layer, and the insulating layer to form at least one via of at least one dual damascene structure;
removing the photoresist layer;
removing the remaining gap filling layer;
forming a barrier layer on a surface of the light blocking layer and the dual damascene structure;
performing a re-sputter process to expose the conductive region;
forming a seed layer on a surface of the barrier layer and the exposed conductive region; and
forming a metal layer on a surface of the seed layer, and the metal layer filling up the a dual damascene structure.

8. The method of claim 1 wherein the conductive region is the first alignment mark, and the recess is formed aside the conductive region.

9. The method of claim 8 wherein the composite layer is used to prevent light from reaching to the conductive region when aligning the photo mask with the recess to improve alignment accuracy.

10. The method of claim 1 wherein the hard mask layer is a titanium nitride layer (TiN layer).

11. The method of claim 10 wherein a thickness of the titanium nitride layer is approximately 250 angstroms (Å).

12. The method of claim 1 wherein the light blocking layer comprises a titanium nitride layer or a tantalum nitride layer (TaN layer).

13. The method of claim 12 wherein a thickness of the titanium nitride layer is approximately 250 angstroms (Å).

14. The method of claim 1 wherein the gap filling layer is a bottom anti-reflective coating (BARC) and is formed by a spin coating process.

15. A method of forming at least one wire on a substrate, the substrate comprising at least one first conductive region and at least one second conductive region, wherein the second conductive region is utilized as a first alignment mark, an insulating layer disposed on the substrate, the method comprising:
forming a hard mask layer on a surface of the insulating layer;
forming at least one first recess above the first conductive region and at least one second recess aside the second conductive region by removing portions of the hard mask layer and portions of the insulating layer;
forming a light blocking layer on a surface of the hard mask layer, the first recess, and the second recess, the light blocking layer and the hard mask layer forming a composite layer;
forming a gap filling layer on a surface of the light blocking layer, and the gap filling layer filling up the first recess and the second recess;
forming a photoresist layer on a surface of the gap filling layer;
aligning a photo mask with the second recess by utilizing the composite layer as a mask, wherein the second recess is utilized as a second alignment mark, and light is prevented from reaching to the first alignment mark when aligning the photo mask with the second alignment mark to achieve two direct alignments; and
performing an exposure and development process to form at least one pattern above the first recess in the photoresist layer.

16. The method of claim 15 wherein the substrate comprises a semiconductor wafer or a silicon-on-insulator substrate (SOI substrate).

17. The method of claim 15 wherein the first conductive region comprises a source of a transistor, a gate of a transistor, a drain of a transistor, a lower level wire, a landing pad, or a resistor.

18. The method of claim 17 wherein the first recess exposes the first conductive region.

19. The method of claim 18 further comprising the following steps after forming the pattern in the photoresist layer:
performing an etching process by utilizing the photoresist layer as a mask to remove portions of the gap filling layer, the light blocking layer, the hard mask layer, and the insulating layer to form at least one trench of at least one dual damascene structure;
removing the photoresist layer;
removing the remaining gap filling layer;
forming a barrier layer on a surface of the light blocking layer and the dual damascene structure;
performing a re-sputter process to expose the first conductive region;
forming a seed layer on a surface of the barrier layer and the exposed first conductive region; and
forming a metal layer on a surface of the seed layer, and the metal layer filling up the dual damascene structure.

20. The method of claim 17 wherein the first recess does not expose the first conductive region.

21. The method of claim 20 further comprising the following steps after forming the pattern in the photoresist layer:
performing an etching process by utilizing the photoresist layer as a mask to remove portions of the gap filling layer, the light blocking layer, the hard mask layer, and the insulating layer to form at least one via of at least one dual damascene structure;
removing the photoresist layer;
removing the remaining gap filling layer;
forming a barrier layer on a surface of the light blocking layer and the dual damascene structure;
performing a re-sputter process to expose the first conductive region;
forming a seed layer on a surface of the barrier layer and the exposed first conductive region; and
forming a metal layer on a surface of the seed layer, and the metal layer filling up the a dual damascene structure.

22. The method of claim 15 wherein the second conductive region is the first alignment mark, and the composite layer is used to prevent light from reaching to the second conductive region when aligning the photo mask with the second recess to improve alignment accuracy.

23. The method of claim 15 wherein the hard mask layer is a titanium nitride layer (TiN layer).

24. The method of claim 23 wherein a thickness of the titanium nitride layer is approximately 250 angstroms (Å).

25. The method of claim 15 wherein the light blocking layer comprises a titanium nitride layer or a tantalum nitride layer (TaN layer).

26. The method of claim 25 wherein a thickness of the titanium nitride layer is approximately 250 angstroms (Å).

27. The method of claim 15 wherein the gap filling layer is a bottom anti-reflective coating (BARC) and is formed by a spin coating process.

28. A method of forming at least one wire on a substrate, the substrate comprising at least one first conductive region and at least one second conductive region, wherein the second conductive region is utilized as a first alignment mark, an insulating layer disposed on the substrate, the method comprising:
forming at least one first recess above the first conductive region and at least one second recess aside the second conductive region by removing portions of the insulating layer;
forming a bottom anti-reflective coating (BARC) on a surface of the insulating layer, the first recess, and the second recess, and the bottom anti-reflective coating filling up the first recess;
forming a photoresist layer on a surface of the bottom anti-reflective coating, and the photoresist layer filling up the second recess;
aligning a photo mask with the second recess by utilizing the bottom anti-reflective coating as a mask, wherein the second recess is utilized as a second alignment mark, and light is prevented from reaching to the first alignment mark when aligning the photo mask with the second alignment mark to achieve two direct alignments; and
performing an exposure and development process to form at least one pattern above the first recess in the photoresist layer.

29. The method of claim 28 wherein the substrate comprises a semiconductor wafer or a silicon-on-insulator substrate (SOI substrate).

30. The method of claim 28 wherein the first conductive region comprises a source of a transistor, a gate of a transistor, a drain of a transistor, a lower level wire, a landing pad, or a resistor.

31. The method of claim 30 wherein the first recess exposes the first conductive region.

32. The method of claim 31 further comprising the following steps after forming the pattern in the photoresist layer:
performing an etching process by utilizing the photoresist layer as a mask to remove portions of the bottom anti-reflective coating and the insulating layer to form at least one trench of at least one dual damascene structure;
removing the photoresist layer;
removing the remaining bottom anti-reflective coating;
forming a barrier layer on a surface of the insulating layer and the dual damascene structure;
performing a re-sputter process to expose the first conductive region;
forming a seed layer on a surface of the barrier layer and the exposed first conductive region; and
forming a metal layer on a surface of the seed layer, and the metal layer filling up the dual damascene structure.

33. The method of claim 30 wherein the first recess does not expose the first conductive region.

34. The method of claim 33 further comprising the following steps after forming the pattern in the photoresist layer:
performing an etching process by utilizing the photoresist layer as a mask to remove portions of the bottom anti-reflective coating and the insulating layer to form at least one via of at least one dual damascene structure;
removing the photoresist layer;
removing the remaining bottom anti-reflective coating;
forming a barrier layer on a surface of the insulating layer and the dual damascene structure;
performing a re-sputter process to expose the first conductive region;
forming a seed layer on a surface of the barrier layer and the exposed first conductive region; and
forming a metal layer on a surface of the seed layer, and the metal layer filling up the a dual damascene structure.

35. The method of claim 28 wherein the second conductive region is the first alignment mark, and the bottom anti-reflective coating is used to prevent light from reaching to the second conductive region when aligning the photo mask with the second recess to improve alignment accuracy.

36. The method of claim 28 wherein the bottom anti-reflective coating is a light absorptive coating.

37. The method of claim 28 wherein a thickness of the bottom anti-reflective coating is approximately 600-1200 angstroms (Å).

38. The method of claim 28 wherein the bottom anti-reflective coating is composed of organic materials, and the bottom anti-reflective coating is formed by a spin coating process.

39. The method of claim 38 wherein the organic materials comprises dyes.
